(19) United States
(12) Patent Application Publication
(10) Pub. No.: US 2026/0068057 A1
(43) Pub. Date: Mar. 5, 2026

(54) FLEXIBLE CIRCUIT BOARD, LIGHT RECEIVING/TRANSMITTING ASSEMBLY, OPTICAL MODULE, AND CONNECTION METHOD

(71) Applicant: InnoLight Technology (Suzhou) Ltd., Suzhou (CN)

(72) Inventors: Bin Lv, Suzhou (CN); Jia Gu, Suzhou (CN); XIANGZHONG WANG, Suzhou (CN); Yong Zhang, Suzhou (CN); Zhenzhong WANG, Suzhou (CN); Xigui Fang, Suzhou (CN); Zhendong Xu, Suzhou (CN); Guodong Liang, Suzhou (CN); Chao Wang, Suzhou (CN); PENG CHEN, Suzhou (CN)

(21) Appl. No.: 19/386,241

(22) Filed: Nov. 12, 2025

Related U.S. Application Data
(63) Continuation of application No. PCT/CN2024/090316, filed on Apr. 28, 2024.

(30) Foreign Application Priority Data
May 17, 2023 (CN) 202310557974.9

(51) Int. Cl. H05K 1/18; H05K 1/02; H05K 1/11

(52) U.S. Cl. CPC H05K 1/189; H05K 1/025; H05K 1/113; H05K 2201/093; H05K 2201/0939; H05K 2201/09609; H05K 2201/09854; H05K 2201/10121

(57) ABSTRACT

A flexible circuit board, a light receiving/transmitting assembly, an optical module, and a connection method. The flexible circuit board includes a top metal layer having a high-speed signal line formed therein, a substrate, and a bottom metal layer having a ground zone formed therein which are sequentially stacked in a thickness direction. The high-speed signal line has a high-speed-signal via a pad located at one end of the flexible circuit board and electrically connected to an external high-speed pin. The top metal layer has an auxiliary ground reference formed therein. The auxiliary ground reference is disposed neighboring the high-speed signal line and stacked with the ground zone. The auxiliary ground reference is electrically connected to the ground zone by means of an auxiliary conductive hole, and the auxiliary ground reference and/or the ground zone is provided with a ground via pad electrically connected to an external ground pin.

### CROSS-REFERENCE TO RELATED PATENT APPLICATION

This application is a continuation application of International Patent Application Ser. No. PCT/CN2024/090316, filed on Apr. 28, 2024, which the international application was published on Nov. 21, 2024, as International Publication No. WO 2024/234982A1, and claims the priority of China Patent Application No. CN202310557974.9, filed on May 17, 2023 in People's Republic of China. The entirety of each of the above patent applications is hereby incorporated by reference herein and made a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### TECHNICAL FIELD

The present invention belongs to the technical field of optical communication component manufacturing, and specifically relates to a flexible circuit board, an optical receiving/transmitting component and an optical module having the flexible circuit board, and a method for connecting the flexible circuit board with an optical device.

### BACKGROUND ART

With the continuous development of optical communication technologies and the increasing data traffic in data centers, optical modules have rapidly evolved from 25G NRZ to 50G PAM4 and even 100G PAM4. However, as cost continues to decrease and reliability requirements continue to increase, the design of optical modules faces significant challenges. In applications targeting the 5G market, the optical module is required to be fully hermetically sealed, with stringent requirements for both reliability and cost.

A conventional TO-packaged optical module comprises a printed circuit board (PCB), a flexible circuit board (FCB), and a TO-CAN package. One end of the flexible circuit board is electrically connected to the printed circuit board, and the other end is electrically connected to the pins of the TO-CAN, thereby forming a high-speed link between the PCB and the TO-CAN via the flexible circuit board.

However, in the structural design of conventional flexible circuit boards, high-speed signal lines are routed on the top surface of the flexible circuit board and are connected to high-speed signal via pads, while the ground (GND) reference is routed on the bottom surface of the flexible circuit board. After the high-speed pins of the TO-CAN are soldered to the high-speed signal via pads of the flexible circuit board, the high-speed pins of the TO-CAN and the high-speed signal lines of the flexible circuit board are far away from the GND reference. This results in insufficient GND referencing around the high-speed link, causing impedance discontinuities, instability, and reduced bandwidth, which in turn affects the overall reliability of the optical module.

### SUMMARY OF THE INVENTION

The object of the present invention is to provide a flexible circuit board, a light receiving/transmitting assembly and an optical module having the flexible circuit board, and a method for connecting a flexible circuit board with an optical device, so as to solve the problem of missing GND reference around a high-speed link in the prior art.

To achieve the above objective, one embodiment provides a flexible circuit board, comprising a top metal layer, a substrate, and a bottom metal layer sequentially stacked in a thickness direction, in which the bottom metal layer has a ground zone, and the top metal layer defines a high-speed signal line;
wherein the high-speed signal line comprises a high-speed signal via pad located at one end of the flexible circuit board and electrically connected to an external high-speed pin; and
wherein the top metal layer further defines an auxiliary ground reference disposed around the high-speed signal line, and the auxiliary ground reference is arranged adjacent to the high-speed signal line and vertically stacked with the ground zone; wherein the auxiliary ground reference is electrically connected to the ground zone through an auxiliary conductive hole; and wherein the auxiliary ground reference and/or the ground zone is provided with a ground via pad electrically connected to an external ground pin.

As a further improvement of an embodiment, the flexible circuit board comprises a front-end gold finger area, a rear-end welding area provided with the high-speed signal via pad, and a middle area connecting the gold finger area and the welding area; and
wherein the auxiliary ground reference extends from the gold finger area to the welding area along the high-speed signal line.

As a further improvement of an embodiment, the auxiliary conductive hole comprises a plurality of first conductive holes located in the middle area and arranged along the high-speed signal line.

As a further improvement of an embodiment, the auxiliary ground reference and the first conductive holes are disposed on opposite sides of the high-speed signal line.

As a further improvement of an embodiment, at least a portion of the first conductive holes are symmetrically distributed on opposite sides of the high-speed signal line.

As a further improvement of an embodiment, a distance between two adjacent first conductive holes at a front end of the middle area is smaller than a distance between two adjacent first conductive holes at a rear end of the middle area.

As a further improvement of an embodiment, the flexible circuit board comprises a front-end gold finger area and a rear-end welding area provided with the high-speed signal via pad and the ground via pad; and
wherein the auxiliary conductive hole comprises one, two, or more second conductive holes located in the welding area; and wherein a distance between the second conductive holes and the high-speed signal via pad is smaller than a distance between the ground via pad and the high-speed signal via pad.

As a further improvement of an embodiment, the second conductive hole is provided on one side or on both sides of an end of the high-speed signal line.

As a further improvement of an embodiment, a plurality of the second conductive holes are distributed around the high-speed signal via pad, and the auxiliary ground reference extends around the high-speed signal via pad from one side of the high-speed signal line to the other side.

As a further improvement of one embodiment, a hollow cavity is defined at a center of the second conductive hole.

As a further improvement of an embodiment, the second conductive hole is configured to be circular, and a diameter of the central cavity is not less than 0.1 mm; or
wherein the second conductive hole is configured to be elliptical or hourglass-shaped, a major axis thereof is substantially parallel to a tangent of the adjacent high-speed signal line or the adjacent high-speed signal via pad, and a minor axis of the central cavity is not less than 0.1 mm.

As a further improvement of an embodiment, the ground via pad is located closer to the gold finger area than the high-speed signal via pad.

As a further improvement of an embodiment, the flexible circuit board further comprises a top insulating film covering the top metal layer and/or a bottom insulating film covering the bottom metal layer; and
wherein the bottom insulating film comprises a window in the welding area to expose the second conductive hole.

To achieve the above objective, an embodiment provides a light receiving/transmitting assembly, characterized by comprising: a flexible circuit board, wherein the flexible circuit board comprises a top metal layer, a substrate and a bottom metal layer stacked in sequence in a thickness direction, the bottom metal layer is formed with a ground zone, and the top metal layer is formed with a high-speed signal line;
wherein a high-speed signal via pad is provided at the end of the high-speed signal line;
wherein the top metal layer is also formed with an auxiliary ground reference located around the high-speed signal line, the auxiliary ground reference is electrically connected to the ground zone through an auxiliary conductive hole, and the auxiliary ground reference and/or the ground zone is provided with a ground via pad; and
wherein the light receiving/transmitting assembly also comprises an optical device, which comprises a sealed shell and a light-emitting element or a light-receiving element located inside the sealed shell. The ground base of the sealed shell has protruding high-speed pins and ground pins; the high-speed pins and the ground pins are respectively inserted from one side of the bottom surface of the flexible circuit board and welded to the high-speed signal via pad and the ground via pad.

As a further improvement of an embodiment, the flexible circuit board comprises a gold finger area and a welding area provided with the high-speed signal via pad and the ground via pad;
wherein the auxiliary conductive hole comprises one, two, or more second conductive holes located in the welding area; and
wherein the light receiving/transmitting assembly further comprises a solder structure that overflows from the second conductive hole to a position between the ground base of the sealed housing and the ground zone, such that the solder structure electrically connects the ground base of the sealed housing to the ground zone.

As a further improvement of an embodiment, a boss protruding from the ground base is provided at a bottom end of the ground pin.

As a further improvement of an embodiment, a temperature controller is disposed inside the sealed housing, and wherein the temperature controller is fixedly mounted on the ground base of the sealed housing and is thermally coupled to the light-emitting element or the light-receiving element.

To achieve the above objective, one embodiment provides an optical module, which comprises the light receiving/transmitting assembly.

As a further improvement of an embodiment, the flexible circuit board comprises a gold finger area and a welding area connected to the light receiving/transmitting assembly;
wherein the optical module further comprises a printed circuit board electrically connected to the gold finger area; and
wherein the flexible circuit board comprises a bending deformation portion adjacent to the welding area, and the ground via pad is closer to the bending deformation portion than the high-speed signal via pad.

To achieve the above objective, an embodiment provides a method for connecting a flexible circuit board and an optical device, characterized by comprising:
providing a flexible circuit board, the flexible circuit board comprising a top metal layer, a substrate, and a ground zone sequentially stacked in a thickness direction, wherein the top metal layer defines a high-speed signal line and an auxiliary ground reference disposed around the high-speed signal line, wherein the auxiliary ground reference is electrically connected to the ground zone via an auxiliary conductive hole, and wherein the flexible circuit board is further provided with a high-speed signal via pad and a ground via pad;
adding solder into the auxiliary conductive hole;
inserting a high-speed pin and a ground pin of the optical device into the high-speed signal via pad and the ground via pad, respectively, from one side of the ground zone of the flexible circuit board; and
heating and melting the solder, such that the solder electrically connects the ground zone to a ground base of a housing of the optical device.

To achieve the above objective, an embodiment provides a method for connecting a flexible circuit board and an optical device, characterized by comprising:
providing a flexible circuit board, the flexible circuit board including a high-speed signal line, a substrate, and a ground zone sequentially stacked in a thickness direction, and further comprising an auxiliary conductive hole, a high-speed signal via pad, and a ground via pad, wherein a distance between the auxiliary conductive hole and the high-speed signal via pad is less than a distance between the ground via pad and the high-speed signal via pad;
adding solder into the auxiliary conductive hole;
inserting a high-speed pin and a ground pin of the optical device into the high-speed signal via pad and the ground via pad, respectively, from one side of the ground zone of the flexible circuit board; and
heating and melting the solder, such that the solder electrically connects the ground zone to a ground base of a housing of the optical device.

Compared with the prior art, the beneficial effects of the present invention are at least that: by setting an auxiliary ground reference around the high-speed signal line on the top side of the substrate, and electrically connecting the auxiliary ground reference to the ground zone on the bottom side of the substrate through an auxiliary conductive hole, sufficient grounding around the high-speed link is ensured, a coplanar waveguide is formed, the impedance stability is improved, the instability caused by sudden change in impedance is eliminated, and the bandwidth is increased, thereby improving the reliability of the entire module.

### BRIEF DESCRIPTION OF THE DRAWINGS

FIG. 1 is a front view of a bottom surface of a flexible circuit board in one embodiment of the present invention;

FIG. 2 is a front view of a top surface of a flexible circuit board in one embodiment of the present invention;

FIG. 3 is a partial cross-sectional view taken along line C-C in FIG. 2;

FIG. 4 is a partial enlarged view of area A indicated by the dotted line in FIG. 2; and

FIG. 5 is a schematic structural diagram of an optical device in one embodiment of the present invention.

### DETAILED DESCRIPTION

The present invention will be described in detail below in conjunction with the specific embodiments shown in the accompanying drawings. However, these embodiments do not limit the present invention, and any structural, methodological, or functional changes made by a person skilled in the art based on these embodiments are all within the scope of protection of the present invention.

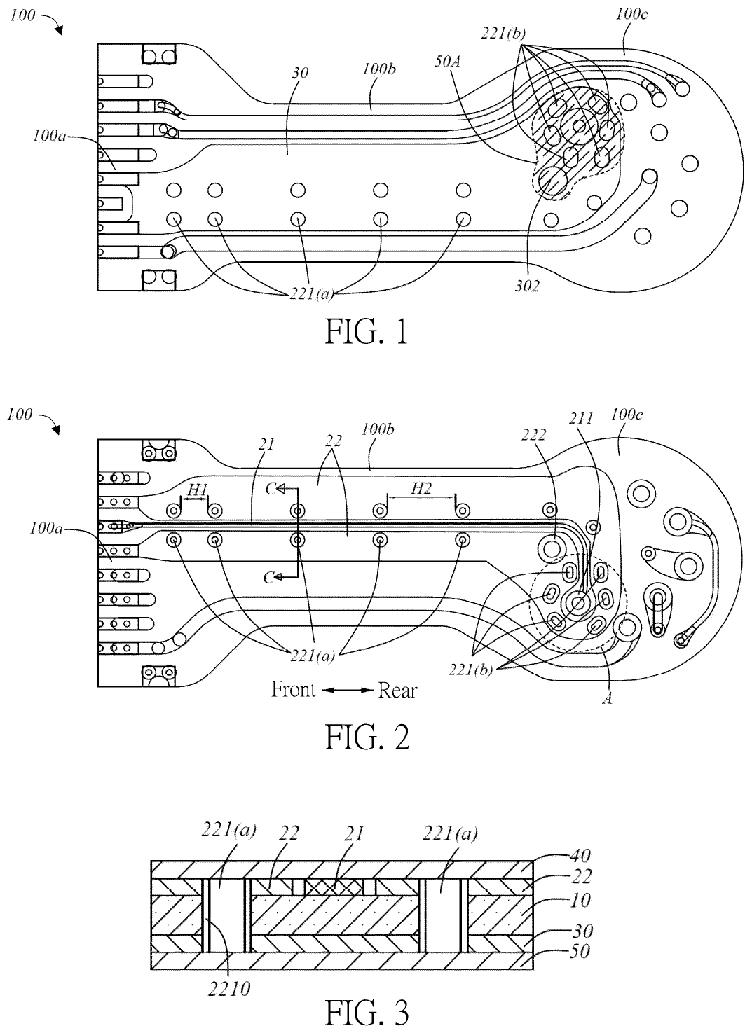

Referring to FIGS. 1 to 4, an embodiment of the present invention provides a flexible circuit board 100.

At least a portion of the flexible circuit board 100 (e.g., the middle area 100b described later) can be bent and deformed in the thickness direction. For example, referring to FIG. 1, the flexible circuit board 100 can be roughly divided into a gold finger area 100a, a welding area 100c, and a middle area 100b connecting the gold finger area 100a and the welding area 100c; the welding area 100c can be welded and electrically connected to an external component (e.g., the optical device 600 described later, see FIG. 5 for the reference numeral), the gold finger area 100a can be electrically connected to another external component (e.g., a printed circuit board), and the middle area 100b can be bent and deformed to realize the overall position layout of the two external components (e.g., the printed circuit board, the optical device 600).

Structurally, the flexible circuit board 100 comprises a top metal layer (e.g., a layer indicated by reference numerals 22 and 21 in FIG. 3), a substrate 10, and a bottom metal layer (e.g., a layer indicated by reference numeral 30 in FIG. 3) stacked sequentially in the thickness direction.

Among them, the substrate 10 is the supporting structure layer of the flexible circuit board 100, which can be specifically configured as a single-layer board structure or a multi-layer board structure. In FIG. 3 of the present embodiment, the substrate 10 is exemplified as a single-layer insulating board, the material of which is liquid crystal polymer, polyimide, polypropylene or Teflon. Certainly, the substrate 10 can also be a multi-layer board including at least two layers of insulating boards, each layer of which is made of liquid crystal polymer, polyimide, polypropylene or Teflon, and the adjacent two layers of insulating boards can be bonded and fixed or clamped with inner layer circuits by adhesives (such as thermosetting adhesives). These modified implementations of the substrate 10 do not deviate from the intended purpose of the present invention, and it can be seen that the substrate 10 is configured as a single-layer insulating board to achieve the invention purpose of this application, without requiring a complex multi-layer board structure, and the manufacturing cost is low.

The top metal layer and the bottom metal layer are respectively covered on two opposite surfaces of the substrate 10 in the thickness direction, and the two are formed with conductive patterns to realize the electrical function of the flexible circuit board 100. In a specific embodiment, the top metal layer and the bottom metal layer can be respectively configured as copper layers. That is, the flexible circuit board 100 is a double-sided copper-clad structure.

Referring to FIG. 1, the bottom metal layer is formed with a ground zone 30, which can be processed by an etching process. The ground zone 30 is provided with a ground via pad 302 located in the welding area 100c, a power via pad for providing power, and some other via pads. The ground via pad 302 is a pad structure with a via hole in the center, which can be inserted into the ground pin of an external component (such as the ground pin 63 of the optical device 600 in FIG. 5) and electrically connected by welding, so as to realize grounding between the flexible circuit board 100 and the external component.

Referring to FIG. 2, the top metal layer is formed with a high-speed signal line 21.

The high-speed signal line 21 has electrical connection ends located at two ends of the flexible circuit board 100 (such as the gold finger area 100a and the welding area 100c) and electrically connected to the external pins. Among them, the electrical connection end at one of the two ends of the flexible circuit board 100 (such as the electrical connection end at the welding area 100c) is configured as a high-speed signal via pad 211, which is a pad structure with a via hole in the center, and can be used for inserting the high-speed pin of the external component (such as the high-speed pin 62 of the optical device 600 in FIG. 5) and performing welding and electrical connecting therewith, so as to achieve a high-speed signal channel between the flexible circuit board 100 and the external component.

As mentioned in the background technology, since the high-speed signal line 21 and the ground zone 30 are distributed on both sides of the substrate 10 and are spaced apart by a relatively large distance, if relying only on the high-speed signal line 21 and the ground zone 30 to electrically connect with external components and establish a high-speed link, it will lead to the loss of GND reference around the high-speed link, the impedance will suddenly change and become unstable, and the bandwidth will decrease, thereby affecting the reliability of the entire module.

In order to solve this technical problem, in the present application, referring to FIG. 2, in addition to forming the high-speed signal line 21, the top metal layer further forms an auxiliary ground reference 22. The auxiliary ground reference 22 is located around the high-speed signal line 21, and the auxiliary ground reference 22 is adjacent to the high-speed signal line 21 and is stacked with the ground zone 30, and the auxiliary ground reference 22 is electrically connected to the ground zone 30 through an auxiliary conductive hole 221. In this way, by setting the auxiliary ground reference 22 around the high-speed signal line 21 on the top side of the substrate 10, and electrically connecting the auxiliary ground reference 22 to the ground zone 30 on the bottom side of the substrate 10 through the auxiliary conductive hole 221, sufficient ground reference around the high-speed link is guaranteed, a coplanar waveguide is formed, the impedance stability is improved, the instability caused by the sudden change in impedance is eliminated, and the bandwidth is increased. As a result, the reliability of the entire module is improved.

Certainly, the top metal layer may also be formed with other signal lines, such as a power signal line for providing power and other signal lines.

The auxiliary conductive hole 221 conducts through the substrate 10 along the thickness direction and electrically connects the auxiliary ground reference 22 and the ground zone 30. Specifically, referring to FIG. 3, it can be seen that the auxiliary conductive hole 221 can be configured as a hole structure with a gold-plated layer 2210 on the inner wall. Certainly, the conductive function of the auxiliary conductive hole 221 is not limited to being realized by the gold-plated layer 2210, and can also be realized by filling other conductive materials in the via structure.

Furthermore, in the present embodiment, the auxiliary ground reference 22 is also provided with a ground via pad 222 located in the welding area 100c, which can be used for the ground pin of the external component (such as the ground pin 63 of the optical device 600 in FIG. 5) to be inserted therein and electrically connected by welding, thereby achieving grounding connect between the flexible circuit board 100 and the external component.

It can be seen in the accompanying drawings that the ground via pad 222 of the auxiliary ground reference 22 of the present embodiment shares the same via with the ground via pad 302 of the ground zone 30. That is, the present embodiment adopts a double-sided ground pad structure to match with a ground pin of an external component. In other words, the auxiliary ground reference 22 and the ground zone 30 are connected through a via, and the auxiliary ground reference 22 forms a ground via pad 222 around the via, and the ground zone 30 forms a ground via pad 302 around the via. Certainly, in a variant embodiment, a single-sided ground pad structure can also be used to match with a ground pin of an external component, for example, only the auxiliary ground reference 22 is provided with a ground via pad 222 and the ground zone 30 is omitted, or conversely, only the ground via pad 302 is provided with a ground via pad 222 and the ground zone 30 is omitted.

As mentioned above, the flexible circuit board 100 has a gold finger area 100a at one end thereof and a welding area 100c at the other end thereof. In this application, for the convenience of explanation and understanding, the front-to-back direction is defined by the relative position of the gold finger area 100a and the welding area 100c when the flexible circuit board 100 is in a flattened state (i.e., in a non-bending deformation state), and the welding area 100c defines a direction “back” relative to the gold finger area 100a, and vice versa, the gold finger area 100a defines a direction “front” relative to the welding area 100c. In this way, the front end of the flexible circuit board 100 is the gold finger area 100a, and the rear end is the welding area 100c.

As described above, for the high-speed signal line 21, the electrical connection end at the other of the two ends of the flexible circuit board 100 (such as the electrical connection end at the gold finger area 100a) is configured as a gold finger terminal. When the flexible circuit board 100 is electrically connected to an external component (such as a printed circuit board), the gold finger terminal of the high-speed signal line 21 establishes a high-speed signal channel with the external component (such as a printed circuit board). In combination with the above, the high-speed signal via pad 211 of the high-speed signal line 21 is located in the welding area 100c, and establishes a high-speed signal channel with another external component (such as an optical device). In this way, the high-speed signal line 21 extends from the gold finger area 100a backward through the middle area 100b to the welding area 100c, thereby forming a high-speed link.

The auxiliary ground reference 22 follows the high-speed signal line 21 and extends from the gold finger area 100a to the welding area 100c. It can be seen that it is at least distributed in the middle area 100b and is located on the side of the high-speed signal line 21. Previously in the conventional flexible circuit board, the high-speed signal line 21 in the middle area 100b is spaced relatively far from the reference ground, leading to a problem of low bandwidth. In the present embodiment, by arranging the auxiliary ground reference 22 in the middle area 100b, the part of the high-speed signal line 21 in the middle area 100b can be positioned in close proximity to the auxiliary ground reference 22, so as to form a sufficient ground reference, further ensure the coplanar waveguide, improve the stability of the impedance, and then ensure the bandwidth.

Further, referring to FIG. 2, the auxiliary ground reference 22 extends continuously from the gold finger area 100a through the middle area 100b to the welding area 100c. Thus, the auxiliary ground reference 22 has a large continuous span in the front-to-back direction, at least spanning the middle area 100b from front to back, thereby ensuring that the high-speed signal line 21 can be close to the reference ground in as many areas as possible in the front-to-back direction.

The auxiliary conductive hole 221 comprises a first conductive hole 221 (a) located in the middle area 100b. In this way, in addition to being grounded through the ground via pad 222 described above, the auxiliary ground reference 22 of the middle area 100b can also be grounded through the first conductive hole 221 (a), so that the auxiliary ground reference 22 of the middle area 100b is directly electrically connected to the ground zone 30 on the bottom surface of the flexible circuit board 100 along the thickness direction to ensure that the auxiliary ground reference 22 of the middle area 100b is fully grounded, which is beneficial to the stability of impedance and improves bandwidth.

The number of the first conductive holes 221 (a) can be one, two or more. In the figure, there are multiple conductive holes. In the present embodiment, when the number is greater, the grounding is more sufficient and the impedance stability is stronger.

The spacing H1 between two adjacent first conductive holes 221 (a) at the front end of the middle area 100b is smaller than the spacing H2 between two adjacent first conductive holes 221 (a) at the rear end of the middle area 100b. In this way, the first conductive holes at the front end of the middle area 100b are arranged more closely, while the first conductive holes at the rear end of the middle area 100b are arranged relatively sparsely, so that the grounding is more sufficient and the impedance stability is stronger, while preventing the hardness at the rear end of the middle area 100b from increasing and affecting the bending performance of the flexible circuit board 100.

Furthermore, auxiliary ground references 22 and first conductive holes 221 (a) are provided on opposite sides of the high-speed signal line 21. In this way, the auxiliary ground references 22 clamp the high-speed signal line 21 from both sides, and the auxiliary ground references 22 on each side can be electrically connected to the ground zone 30 on the bottom surface through the first conductive holes 221 (a) on the side, so that the arrangement ensures more sufficient grounding, maintains the integrity of the signal reference ground, forms a more favorable coplanar waveguide, improves impedance stability, and significantly enhances the bandwidth.

In the present embodiment, at least part of the first conductive holes 221 (a) are symmetrically distributed on opposite sides of the high-speed signal line 21. For example, as shown in the figure, the distances between the two first conductive holes 221 (a) and the gold finger area 100a in the front-to-back direction are substantially the same, and the two first conductive holes 221 (a) are respectively located on opposite sides of the high-speed signal line 21. The distance between the first conductive holes 221 (a) and the gold finger area 100a in the front-to-back direction may be the minimum distance from the outer edge of the gold-plated layer 2210 (or other conductive materials) on the inner wall of the first conductive hole 221 (a) to the gold finger area 100a.

The minimum distances from each first conductive hole 221 (a) to the high-speed signal line 21 are basically consistent, so that better impedance stability can be obtained. The “minimum distance” here can be defined by the minimum distance between the outer edge of the gold-plated layer 2210 (or other conductive material) on the inner wall of the first conductive hole 221 (a) and the high-speed signal line 21.

Furthermore, as shown in the figure, the shape of the first conductive hole 221 (a) is configured to be circular. Certainly, the present application is not limited to this, and it can also be configured to be elliptical, hourglass-shaped, polygonal or other special shapes. These shape changes do not deviate from the technical purpose of the present application.

In addition, referring to FIG. 3, the first conductive hole 221 (a) is exemplified as having a hollow cavity in the center, that is, the gold-plated layer 2210 (or other conductive materials described above) does not completely fill the first conductive hole 221 (a). It can be understood that in the present application, the first conductive hole 221 (a) may also have no hollow cavity in the center and be completely filled with the gold-plated layer 2210 (or other conductive materials described above), and these changes do not deviate from the technical purpose of the present application.

In one embodiment, the auxiliary conductive hole 221 comprises a second conductive hole 221 (b) located in the welding area 100c. In this way, a more sufficient reference ground is formed around the high-speed signal via pad 211, and then after the high-speed signal via pad 211 is electrically connected to the high-speed pin of the external component (such as the high-speed pin 62 of the optical device 600), a more sufficient reference ground is also formed around the high-speed pin of the external component, thereby reducing the sudden change of impedance, while also reducing the leakage of the electromagnetic field, improving the link bandwidth, reducing EMI radiation, and reducing signal crosstalk (for example, when the flexible circuit board 100 is applied to an optical module, reducing the crosstalk between the transmitted and received signals).

Among them, since the auxiliary conductive hole 221 electrically connects the auxiliary ground reference 22 and the ground zone 30 on the bottom surface along the thickness direction, the second conductive hole 221 (b) also electrically connects the auxiliary ground reference 22 and the ground zone 30 on the bottom surface along the thickness direction; and the second conductive hole 221 (b) is located in the welding area 100c of the flexible circuit board 100 as mentioned above, therefore, the auxiliary ground reference 22 is also correspondingly distributed in the welding area 100c of the flexible circuit board 100.

Furthermore, the distance between the second conductive hole 221 (b) and the high-speed signal via pad 211 is smaller than the distance between the ground via pad 222 (and the ground via pad 302) and the high-speed signal via pad 211. In other words, the second conductive hole 221 (b) is closer to the high-speed signal via pad 211. This makes the high-speed return path shorter, further reduces the sudden change in impedance, and improves the link bandwidth.

Among them, the distance between the second conductive hole 221 (b) and the high-speed signal via pad 211 is defined by the minimum distance between the two. For example, the distance between the outer edge of the gold-plated layer 2210 (or the other conductive material) on the inner wall of the second conductive hole 221 (b) and the high-speed signal via pad 211 is the minimum distance between the two. Similarly, the distance between the ground via pad 222 (and the ground via pad 302) and the high-speed signal via pad 211 is defined by the minimum distance between the two.

The number of the second conductive holes 221 (b) can be one, two or more.

In the present embodiment, a plurality of second conductive holes 221 (b) are provided, and these second conductive holes 221 (b) are distributed around the high-speed signal via pad 211. Accordingly, the auxiliary ground reference 22 extends around the high-speed signal via pad 211 from one side of the high-speed signal line 21 to the other side. In this way, the high-speed signal via pad 211 (and the high-speed pin inserted therein) can be surrounded, further reducing the sudden change in impedance, while also reducing the leakage of the electromagnetic field, thereby improving the link bandwidth, reducing EMI radiation, and reducing signal crosstalk (for example, when the flexible circuit board 100 is applied to an optical module, reducing the crosstalk between the transmitted and received signals).

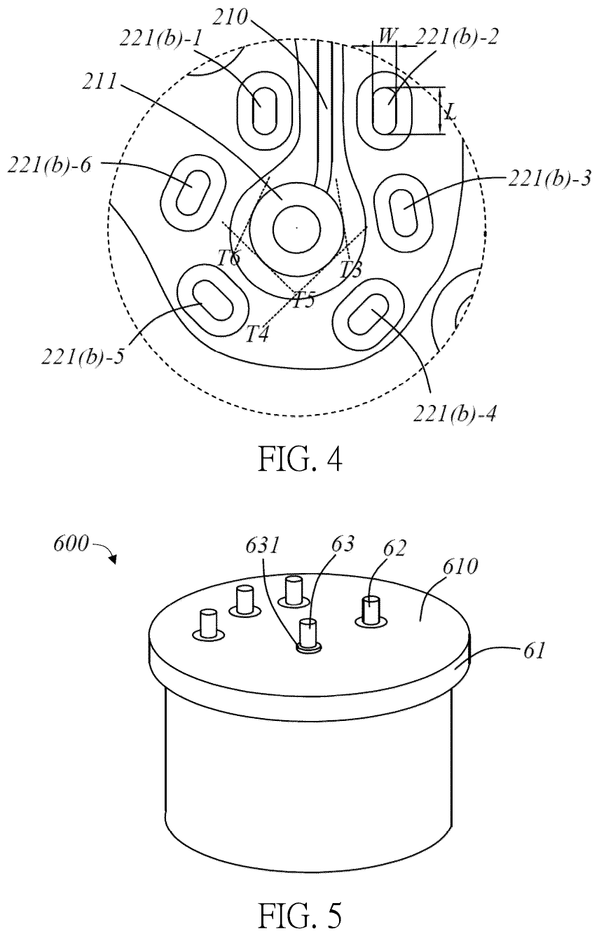

For example, as shown in FIG. 4, the number of the second conductive holes 221 (b) is set to 6, which are respectively marked as second conductive holes 221 (b)-1, 221 (b)-2, 221 (b)-3, 221 (b)-4, 221 (b)-5, and 221 (b)-6. Among them, the second conductive holes 221 (b)-1 and 221 (b)-2 are located on both sides of the end 210 of the high-speed signal line 21; the second conductive holes 221 (b)-5 and 221 (b)-4 are located on the side of the high-speed signal via pad 211 away from the end 210 of the high-speed signal line 21; the second conductive hole 221 (b)-3 is located between the second conductive hole 221 (b)-4 and the second conductive hole 221 (b)-2, and the second conductive hole 221 (b)-6 is located between the second conductive hole 221 (b)-1 and the second conductive hole 221 (b)-5. Certainly, as mentioned above, in an embodiment that is inferior to the example in the accompanying drawings, the number of second conductive holes 221 (b) can be reduced, for example, only the second conductive hole 221 (b)-1 is disposed, or only the second conductive holes 221 (b)-1 and 221 (b)-2 are disposed. Certainly, the number of second conductive holes 221 (b) can be further increased compared to the example in the accompanying drawings to enhance the reference ground surrounding effect.

Furthermore, the center of the second conductive hole 221 (b) has a hollow cavity. Thus, by providing the hollow cavity, when the flexible circuit board 100 is assembled and connected with an external component (such as the optical device 600), solder can be pre-applied through the hollow cavity, and the second conductive hole 221 (b), the auxiliary ground reference 22, the ground zone 30 and the external component (such as the optical device 600) can be fully connected through the solder, thereby avoiding the parasitic capacitance problem caused by the assembly gap and greatly improving the bandwidth.

In the present embodiment, as shown in the attached drawings, the shape of the second conductive hole 221 (b) can be configured to be an hourglass shape or an ellipse shape, and its major axis is substantially parallel to the tangent line of the adjacent high-speed signal line 21 or the adjacent high-speed signal via pad 211. For example, the second conductive holes 221 (b)-1 and 221 (b)-2 are close to the end 210 of the high-speed signal line 21, and the major axes of the two are substantially parallel to the end 210 of the high-speed signal line 21; the second conductive hole 221 (b)-5 is close to the high-speed signal via pad 211, and its major axis is substantially parallel to the tangent line T5 of the high-speed signal via pad 211. Similarly, the major axes of the second conductive holes 221 (b)-3, 221 (b)-4, and 221 (b)-6 are respectively substantially parallel to the tangent lines T3, T4, and T6 of the high-speed signal via pad 211. In this way, the second conductive hole 221 (b) can be prevented from being too large in the direction away from the high-speed signal line 21 or the high-speed signal via pad 211 to cause a short circuit, and the surrounding effect of the reference ground can be increased, the sudden change in impedance can be reduced, and the bandwidth can be improved.

Certainly, the present application is not limited thereto, and the second conductive hole 221 (b) can also be configured to be circular, and these shape changes do not deviate from the technical purpose of the present application.

As shown in the figure, when the second conductive hole 221 (b) is configured to be hourglass-shaped or elliptical, the minor axis W of the hollow cavity is not less than 0.1 mm; if the change is implemented as a circle, the diameter of the hollow cavity is not less than 0.1 mm. In this way, the amount of solder added and the sufficient flow capacity can be guaranteed during assembly and connection, thereby ensuring the connection effect, such as improving the bandwidth.

Furthermore, the ground via pads 222 and 302 are closer to the gold finger area 100a of the flexible circuit board 100 than the high-speed signal via pads 211. In other words, the ground via pads 222 and 302 are relatively forward, while the high-speed signal via pads 211 are relatively backward. In this way, when the flexible circuit board 100 is used (for example, when it is used in an optical module as described below), the central area 100b thereof is bent and deformed, and the ground via pads 222 and 302 can be closer to the bending and deformation position, while the high-speed signal via pads 211 are relatively far away from the bending and deformation position, thereby avoiding the functional circuit breakage at the high-speed signal via pads 211 (for example, the high-speed pin inserted therein will not break). Even if the ground via pads 222 and 302 are broken (for example, the ground pin inserted therein is broken), due to the provision of the second conductive hole 221 (b), sufficient grounding between the flexible circuit board 100 and the external component (for example, the optical device 600) can still be ensured, thereby improving reliability.

In addition, referring to FIG. 1 and FIG. 3, the flexible circuit board 100 further comprises a top insulating film 40 covering the top metal layer and/or a bottom insulating film 50 covering the bottom metal layer, both of which can provide insulation protection for the top metal layer and the bottom metal layer of the flexible circuit board 100.

In the present embodiment, in the welding area 100c, the bottom insulating film 50 has a window to expose the second conductive hole 221 (b), so that when the flexible circuit board 100 is assembled and connected with an external component, the second conductive hole 221 (b) can be fully grounded to the external component. The window can refer to the area surrounded by the dotted line 50A in FIG. 1 (the area is slashed in the figure for illustration), and the area outside the dotted line 50A is the bottom insulating film 50 (in order to show the structure of the bottom metal layer, the bottom insulating film 50 is made transparent in FIG. 1).

In addition, the window also exposes the central via hole of the high-speed signal via pad 211, so that the high-speed pin can be inserted into the high-speed signal via pad 211 during subsequent assembly; and the window also exposes the ground via pad 302, so that the ground pin can be inserted into the ground via pad 302 and welded thereto during subsequent assembly.

In combination with the above, in the present embodiment, the auxiliary ground reference 22 extends from the gold finger area 100a to the welding area 100c, and extends from one side of the high-speed signal line 21 to the other side of the high-speed signal line 21 around the high-speed signal via pad 211. In this way, the high-speed signal line 21 and the high-speed signal via pad 211 are surrounded, thereby improving the integrity of the signal reference ground and facilitating bandwidth improvement.

Next, an embodiment of the present invention further provides a light receiving/transmitting assembly. Referring to FIGS. 1 to 4 and FIG. 5, the light receiving/transmitting assembly comprises the flexible circuit board 100 described above and an optical device 600 assembled and connected to the flexible circuit board 100.

The optical device 600 comprises a sealed housing 61 and an optoelectronic component located in the sealed housing 61. A high-speed pin 62 and a ground pin 63 are protruded from a ground base 610 of the sealed housing 61.

The high-speed pin 62 is inserted from the bottom side of the flexible circuit board 100 and welded to the high-speed signal via pad 211 of the flexible circuit board 100, that is, the ground base 610 is located at the bottom side of the flexible circuit board 100, and the high-speed pin 62 is inserted into the via hole of the high-speed signal via pad 211 and is welded and electrically connected to the pad, and the welding method is specifically, for example, soldering on the front side of the flexible circuit board 100. In this way, the high-speed pin 62 is fixedly connected to the flexible circuit board 100, and an electrical connection of a high-speed signal channel is formed between the high-speed pin 62 and the high-speed signal via pad 211.

The ground pin 62 is inserted from the bottom side of the flexible circuit board 100 and welded to the ground via pad of the flexible circuit board 100. In the embodiment of the attached drawings, as described above, the ground via pad 222 of the auxiliary ground reference 22 and the ground via pad 302 of the ground zone 30 share the same via. In this way, the ground pin 62 is inserted and welded to the ground via pad 222 (and also inserted and welded to the ground via pad 302). The specific welding method is, for example, adding solder to the ground via pad on the front side of the flexible circuit board 100 and heating the welding. Certainly, as described above in the variation embodiment, if only one of the ground via pad 222 and the ground via pad 302 is retained and the other is omitted, the ground pin 62 is inserted and welded to the retained ground via pad.

As described above, in the light receiving/transmitting assembly, the flexible circuit board 100 is provided with an auxiliary ground reference 22 on the top side of the substrate 10 around the high-speed signal line 21, and the auxiliary ground reference 22 is electrically connected to the ground area 30 on the bottom side of the substrate 10 through the auxiliary conductive hole 221. There is sufficient reference ground around the high-speed link formed from the high-speed pin 62 of the optical device 600, through the high-speed signal via pad 211 to the high-speed signal line 21 of the flexible circuit board 100, and a coplanar waveguide is formed, thereby improving the stability of the impedance, eliminating the instability caused by the sudden change in impedance, and thus improving the bandwidth and reliability.

The optical device 600 is configured as a coaxial sealed optical device, which is generally referred to as a TO-CAN in the art. The ground base 610 of the sealed housing 61 is configured as a conductive metal seat structure; the ground base 610 and the pins of its load (including the high-speed pin 62 and the ground pin 63) serve as electrical connection terminals of the optical device 600 to be electrically connected with the flexible circuit board 100; and an optical port is formed on the other side of the sealed housing 61 opposite to the ground base 610, and the optical path inside the optical device 600 is optically connected with the outside through the optical port.

The light receiving/transmitting assembly can be specifically configured as an optical transmitting assembly, and accordingly, the optical device 600 is configured as an optical transmitting device, and the components inside it are configured as a laser chip (LD), which is used to convert the electrical signal received by the high-speed pin 62 from the flexible circuit board 100 into an optical signal, and the optical signal can be transmitted out of the optical device 600 through the optical port. Alternatively, the light receiving/transmitting assembly can also be specifically configured as an optical receiving assembly, and accordingly, the optical device 600 is configured as an optical receiving device, and the components inside it are configured as a light detection chip (PD), which is used to convert the optical signal received by the optical port into an electrical signal, and the electrical signal is transmitted to the flexible circuit board 100 through the high-speed pin 62.

In addition, an optical component may be accommodated inside the sealed housing 61. The optical component is located in the optical path between the element and the optical port. The specific arrangement of the optical component is implemented in a feasible manner known in the art and will not be described in detail here.

Further, as described above, the auxiliary conductive hole 221 of the flexible circuit board 100 comprises one, two or more second conductive holes 221 (b) located in the welding area 100c; the light receiving/transmitting assembly also comprises a solder structure, the solder structure overflows from the second conductive hole 221 (b) to between the ground base 610 of the sealing shell 61 and the ground zone 30 of the flexible circuit board 100, and the solder structure electrically connects the ground base 610 with the ground zone 30. Therefore, by setting the second conductive hole 221 (b), the solder structure is formed through the second conductive hole 221 (b), and then compared with the conventional technology, a more sufficient reference ground can be formed around the high-speed pin 62, reducing the sudden change of impedance and improving the link bandwidth. In addition, signal degradation and short circuit problems can be avoided. Specifically, on the one hand, in conventional technology, the flexible circuit board 100 and the optical device 600 are only connected by welding between the ground via pads 222, 302 and the ground pins 63. For example, the ground pins 63 are inserted into the ground via pads 222, 302, and solder is added to the front side of the flexible circuit board 100 and heated to achieve welding. The added solder needs to pass through the gap between the inner wall of the ground via pads 222, 302 and the ground pins 63 to flow to the bottom side of the flexible circuit board 100. However, this process is very likely to cause insufficient tin penetration (that is, the solder cannot fully flow to the bottom side of the flexible circuit board 100), thereby causing signal degradation. In the present embodiment, the second conductive hole 221 (b) is used to form the ground via pads 222, 302. The solder structure is used to achieve sufficient grounding. Even if the tin penetration at the ground pin 63 is insufficient, the signal degradation problem can be avoided, the stability of the impedance around the high-speed pin 62 is guaranteed, and the link bandwidth is improved. On the other hand, in conventional technology, in order to avoid the aforementioned problem of insufficient tin penetration, the via size of the ground via pads 222 and 302 is sometimes increased to increase the gap between the inner wall of the ground via pads 222 and 302 and the ground pin 63, which can easily lead to overflow tin short circuit between the ground pin 63 and other functional pins (such as the high-speed pin 62). In the present embodiment, when the solder structure is formed through the second conductive hole 221 (b) to achieve sufficient grounding, there is no need to increase the via size of the ground via pads 222 and 302 to avoid the overflow tin short circuit problem.

Furthermore, the bottom end of the ground pin 63 of the optical device 600 is provided with a boss 631 protruding from the ground base 610. Generally, the boss 631 is larger than the via size of the ground via pads 222 and 302, which will cause the ground zone 30 of the flexible circuit board 100 to be unable to fully fit the ground base 610 and form GAP parasitic capacitance, generate resonance, and cause bandwidth reduction. In the present embodiment, the solder structure overflowed from the second conductive hole 221 (b) to the ground base 610 of the sealing shell 61 and the ground zone 30 of the flexible circuit board 100 is used to achieve full grounding interconnection, which can eliminate GAP parasitic capacitance and greatly improve bandwidth without increasing costs. There is no need to increase the via size of the ground via pads 222 and 302 (for example, increase it to allow the boss 631 to pass through) to eliminate the GAP parasitic capacitance, thereby avoiding the risk of overflow tin short circuit caused by such a size increase design.

In addition, a thermostat (TEC) may be contained inside the sealed housing 61 of the optical device 600. The thermostat may be fixedly mounted on the ground base 610 of the sealed housing 61 and be thermally connected to the element (especially the laser chip) to control the temperature of the element and ensure that the element works at a suitable temperature. In the embodiment in which the thermostat is provided, by providing the second conductive hole 221 (b) and the solder structure, the thermostat may be prevented from being damaged by long-term high-temperature heating in order to ensure sufficient grounding in the conventional technology while ensuring sufficient grounding, thereby increasing the service life of the thermostat.

Next, an embodiment of the present invention further provides a method for connecting a flexible circuit board and an optical device, for example, for connecting the flexible circuit board 100 and the optical device 600 described above. The connection method is described below in conjunction with FIGS. 1 to 5, and the specific structures of the flexible circuit board 100 and the optical device 600 can be referred to in the above description and will not be repeated.

The connection method comprises the following steps:
providing a flexible circuit board 100 and an optical device 600;
adding solder into the auxiliary conductive hole 221;
inserting the high-speed pin 62 and the ground pin 63 of the optical device 600 into the high-speed signal via pad 211 and the ground via pad 222, 302 from one side of the ground zone 30 of the flexible circuit board 100, respectively; and
heating and melting the solder, such that the solder electrically connects the ground zone 30 and the ground base 610.

In this way, an auxiliary conductive hole 221 (specifically, the second conductive hole 221 (b) described above) is set through the flexible circuit board 100, and solder is pre-added in the auxiliary conductive hole 221. This part of the solder is heated to melt for forming the solder structure that electrically connects the ground zone 30 and the ground base 610. Therefore, compared with the conventional technology, a more sufficient reference ground can be formed around the high-speed pin 62, so as to reduce the sudden change of impedance. Without increasing the cost, problems such as signal degradation, short circuit, GAP parasitic capacitance and thermal damage of the thermostat can also be avoided, thereby greatly improving the link bandwidth and ensuring the overall stability and reliability.

In the step of “adding solder to the auxiliary conductive hole 221”, the solder can be added to the auxiliary conductive hole 221 from the bottom side of the flexible circuit board 100; and in the step of “heating and melting the solder”, the solder can be heated on the top side of the flexible circuit board 100. This is convenient and easy to operate.

Furthermore, the connection method further comprises:
after the step of “inserting the high-speed pin 62 and the ground pin 63 of the optical device 600 into the high-speed signal via pad 211 and the ground via pad 222, 302 from the side of the ground zone 30 of the flexible circuit board 100, respectively”, adding solder to the high-speed signal via pad 211 and the ground via pad 222, 302 from the top surface side of the flexible circuit board 100, so that the high-speed pin 62 is soldered to the high-speed signal via pad 211, and the ground pin 63 is soldered to the ground via pad 222, 302.

In addition, it can be understood that in the step of “adding solder into the auxiliary conductive hole 221”, the amount of solder added is based on the principle of ensuring that the resulting solder structure fully connects the ground zone 30 and the ground base 610, and is as close to the high-speed pin 62 as possible without contacting the high-speed pin 62 (that is, without causing a short circuit).

Next, an embodiment of the present invention further provides an optical module, the optical module comprises the optical receiving/transmitting assembly described above, and accordingly, comprises the flexible circuit board 100 described above, and the connection structure between the flexible circuit board 100 and the optical device 600 can also be as described above. Compared with the prior art, the optical module also has the various beneficial effects mentioned above, which will not be repeated.

Furthermore, the optical module also comprises a printed circuit board (PCBA) electrically connected to the gold finger area 100a of the flexible circuit board 100. For example, the printed circuit board is electrically connected to the high-speed signal line 21 of the gold finger area 100a to form a high-speed signal channel, and the printed circuit board is electrically connected to the ground zone 30 and/or the auxiliary ground reference 22 of the gold finger area 100a to form a ground. In this way, a high-speed link and a return ground can be established from the printed circuit board through the flexible circuit board 100 to the optical device 600. In combination with the foregoing, it can be seen that the impedance stability of the high-speed link of the optical module of the present embodiment is strong, the bandwidth is greatly improved, and the overall reliability of the optical module is strong and the cost is low.

Furthermore, the flexible circuit board 100 is bent between the printed circuit board and the optical device 600, and has a bending deformation position close to the welding area 100c, which is roughly located in the middle and rear section of the middle area 100b, and the ground via pads 222 and 302 are closer to the bending deformation position than the high-speed signal via pads 211. Thus, the high-speed pin 62 at the high-speed signal via pad 211 is prevented from breaking, and even if the ground pin 63 at the ground via pads 222 and 302 is broken, due to the setting of the second conductive hole 221 (b), sufficient grounding between the flexible circuit board 100 and the optical device 600 can still be guaranteed, thereby improving reliability.

It should be understood that although the present specification is described according to embodiments, not every embodiment contains only one independent technical solution. This description of the specification is only for the sake of clarity. Those skilled in the art should regard the specification as a whole. The technical solutions in each embodiment may also be appropriately combined to form other implementation methods that can be understood by those skilled in the art.

The series of detailed descriptions listed above are only specific descriptions of feasible implementation methods of the present invention. They are not intended to limit the scope of protection of the present invention. Any equivalent implementation methods or changes that do not deviate from the technical spirit of the present invention should be included in the scope of protection of the present invention.

1. A flexible circuit board, comprising a top metal layer, a substrate, and a bottom metal layer sequentially stacked in a thickness direction, in which the bottom metal layer is formed with a ground zone, and the top metal layer is formed with a high-speed signal line;
wherein the high-speed signal line comprises a high-speed signal via pad located at one end of the flexible circuit board and electrically connected to an external high-speed pin; and wherein the top metal layer is further formed with an auxiliary ground reference disposed around the high-speed signal line, and the auxiliary ground reference is arranged adjacent to the high-speed signal line and vertically stacked with the ground zone; wherein the auxiliary ground reference is electrically connected to the ground zone through an auxiliary conductive hole; and wherein the auxiliary ground reference and/or the ground zone is provided with a ground via pad electrically connected to an external ground pin.

2. The flexible circuit board according to claim 1, characterized in that the flexible circuit board comprises a front-end gold finger area, a rear-end welding area provided with the high-speed signal via pad, and a middle area connecting the gold finger area and the welding area; and
wherein the auxiliary ground reference extends from the gold finger area to the welding area along the high-speed signal line.

3. The flexible circuit board according to claim 2, characterized in that the auxiliary conductive hole comprises a plurality of first conductive holes located in the middle area and arranged along the high-speed signal line.

4. The flexible circuit board according to claim 3, characterized in that the auxiliary ground reference and the first conductive holes are disposed on opposite sides of the high-speed signal line.

5. The flexible circuit board according to claim 4, characterized in that at least a portion of the first conductive holes are symmetrically distributed on opposite sides of the high-speed signal line.

6. The flexible circuit board according to claim 3, characterized in that a distance between two adjacent first conductive holes at a front end of the middle area is smaller than a distance between two adjacent first conductive holes at a rear end of the middle area.

7. The flexible circuit board according to claim 1, characterized in that the flexible circuit board comprises a front-end gold finger area and a rear-end welding area provided with the high-speed signal via pad and the ground via pad;
wherein the auxiliary conductive hole comprises one, two, or more second conductive holes located in the welding area; and
wherein a distance between the second conductive holes and the high-speed signal via pad is smaller than a distance between the ground via pad and the high-speed signal via pad.

8. The flexible circuit board according to claim 7, characterized in that the second conductive hole is provided on one side or on both sides of an end of the high-speed signal line.

9. The flexible circuit board according to claim 7, characterized in that a plurality of the second conductive holes are distributed around the high-speed signal via pad, and the auxiliary ground reference extends around the high-speed signal via pad from one side of the high-speed signal line to the other side.

10. The flexible circuit board according to claim 7, characterized in that a center of the second conductive hole defines a hollow cavity.

11. The flexible circuit board according to claim 10, characterized in that the second conductive hole is configured to be circular, and a diameter of the central cavity is not less than 0.1 mm; or
wherein the second conductive hole is configured to be elliptical or hourglass-shaped, a major axis thereof is substantially parallel to a tangent of the adjacent high-speed signal line or the adjacent high-speed signal via pad, and a minor axis of the central cavity is not less than 0.1 mm.

12. The flexible circuit board according to claim 7, characterized in that the ground via pad is located closer to the gold finger area than the high-speed signal via pad.

13. The flexible circuit board according to claim 7, characterized in that the flexible circuit board further comprises a top insulating film covering the top metal layer and/or a bottom insulating film covering the bottom metal layer; and
wherein the bottom insulating film comprises a window in the welding area to expose the second conductive hole.

14. A light receiving/transmitting assembly, characterized by comprising:
a flexible circuit board, which is the flexible circuit board according to claim 1; and
an optical device, comprising a sealed housing and a light-emitting element or a light-receiving element disposed within the sealed housing, wherein a high-speed pin and a ground pin protrude from a ground base of the sealed housing, and wherein the high-speed pin and the ground pin are respectively inserted from one side of a bottom surface of the flexible circuit board and soldered to the high-speed signal via pad and the ground via pad.

15. The light receiving/transmitting assembly according to claim 14, characterized in that the flexible circuit board comprises a gold finger area and a welding area provided with the high-speed signal via pad and the ground via pad;
wherein the auxiliary conductive hole comprises one, two, or more second conductive holes located in the welding area; and
wherein the light receiving/transmitting assembly further comprises a solder structure that overflows from the second conductive hole to a position between the ground base of the sealed housing and the ground zone, and the solder structure electrically connects the ground base of the sealed housing to the ground zone.

16. The light receiving/transmitting assembly according to claim 15, characterized in that a boss protruding from the ground base is provided at a bottom end of the ground pin.

17. The light receiving/transmitting assembly according to claim 15, characterized in that a temperature controller is disposed inside the sealed housing, and wherein the temperature controller is fixedly mounted on the ground base of the sealed housing and is thermally coupled to the light-emitting element or the light-receiving element.

18. An optical module, characterized by comprising the light receiving/transmitting assembly according to claim 14.

19. The optical module according to claim 18, characterized in that the flexible circuit board comprises a gold finger area and a welding area connected to the light receiving/transmitting assembly;
wherein the optical module further comprises a printed circuit board electrically connected to the gold finger area; and
wherein the flexible circuit board comprises a bending deformation portion adjacent to the welding area, and the ground via pad is closer to the bending deformation portion than the high-speed signal via pad.

20. A method for connecting a flexible circuit board and an optical device, characterized by comprising:
providing a flexible circuit board, the flexible circuit board comprising a top metal layer, a substrate, and a ground zone sequentially stacked in a thickness direction, wherein the top metal layer defines a high-speed signal line and an auxiliary ground reference disposed around the high-speed signal line, wherein the auxiliary ground reference is electrically connected to the ground zone via an auxiliary conductive hole, and wherein the flexible circuit board is further provided with a high-speed signal via pad and a ground via pad;
adding solder into the auxiliary conductive hole;
inserting a high-speed pin and a ground pin of the optical device into the high-speed signal via pad and the ground via pad, respectively, from one side of the ground zone of the flexible circuit board; and
heating and melting the solder, such that the solder electrically connects the ground zone to a ground base of a housing of the optical device.

21. A method for connecting a flexible circuit board and an optical device, characterized by comprising:
providing a flexible circuit board, the flexible circuit board including a high-speed signal line, a substrate, and a ground zone sequentially stacked in a thickness direction, and further comprising an auxiliary conductive hole, a high-speed signal via pad, and a ground via pad, wherein a distance between the auxiliary conductive hole and the high-speed signal via pad is less than a distance between the ground via pad and the high-speed signal via pad;
adding solder into the auxiliary conductive hole;
inserting a high-speed pin and a ground pin of the optical device into the high-speed signal via pad and the ground via pad, respectively, from one side of the ground zone of the flexible circuit board; and
heating and melting the solder, such that the solder electrically connects the ground zone to a ground base of a housing of the optical device.
